(19) United States
(12) Patent Application Publication
(10) Pub. No.: US 2025/0008691 A1
(43) Pub. Date: Jan. 2, 2025

(54) RETRACTABLE COVER FOR IMMERSION COOLING SYSTEM

(71) Applicant: LIQUIDSTACK HOLDING B.V., Amsterdam (NL)

(72) Inventors: Kar-Wing Lau, Hong Kong (HK); Wai Sing Cheng, Hong Kong (HK); Joseph Capes, Northborough, MA (US)

(21) Appl. No.: 18/759,038

(22) Filed: Jun. 28, 2024

Related U.S. Application Data
(63) Continuation of application No. PCT/IB2023/000009, filed on Jan. 1, 2023.
Application No. PCT/IB2023/000009 is a continuation-in-part of application No. 17/567,123, filed on Jan. 1, 2022, now Pat. No. 11,608,217.
(60) Provisional application No. 63/295,866, filed on Jan. 1, 2022.

(51) Int. Cl. H05K 7/20

(52) U.S. Cl. CPC H05K 7/20327; H05K 7/203

(57) ABSTRACT

An immersion cooling system may include an immersion tank filled with dielectric fluid. To reduce vapor loss when accessing the tank, a retractable cover sheet assembly may be provided. The assembly may include a case having side walls defining an opening. A retractable cover sheet may be located above the opening of the case. The retractable cover sheet may be movable from a first position to a second position to provide a sized opening that is smaller than the opening of the case. A condenser may be mounted to a side wall of the case. The condenser may condense dielectric vapor at or near the sized opening. The condenser may be recessed from the sized opening to avoid interfering with servers being raised or lowered through the sized opening during hot swapping or servicing. Other examples may be claimed or described.

### CROSS-REFERENCE

Pursuant to 35 U.S.C. 120 and 365 (c), this application is a continuation of International Application PCT/IB2023/000009, filed on Jan. 1, 2023, which designates the United States and claims priority to U.S. application Ser. No. 17/567,123 filed on Jan. 1, 2022, now U.S. Pat. No. 11,608,217, and U.S. Application No. 63/295,866 filed on Jan. 1, 2022, each of which is hereby incorporated by reference in its entirety.

### FIELD

The present disclosure relates to immersion cooling systems and, more specifically, to retractable cover assemblies for reducing vapor loss from an immersion tank.

### BACKGROUND

Data centers house information technology (IT) equipment for the purposes of storing, processing, and disseminating data and applications. IT equipment may include electronic devices, such as servers, storage systems, power distribution units, routers, switches, and firewalls.

IT equipment consumes electricity and produces waste heat as a byproduct. A data center with many operating servers requires a dedicated IT cooling system to manage the waste heat. The waste heat may be captured and rejected outside the data center. If the waste heat is not removed, ambient temperature within the data center may rise above an acceptable threshold and temperature-induced performance throttling of electronic devices (e.g., microprocessors) may occur, which is undesirable.

Direct liquid cooling systems can be used to cool IT equipment. One form of direct liquid cooling is immersion cooling. In an immersion cooling system, an electronic device is immersed in dielectric fluid. Waste heat from the electronic device is transferred to the fluid and then captured from the fluid and rejected outside the data center through a suitable heat rejection system.

Examples of immersion cooling may include single-phase immersion cooling and two-phase immersion cooling. In two-phase immersion cooling, waste heat generated by the IT equipment is transferred to the dielectric fluid, causing a portion of the fluid to boil and vaporize to form a dielectric vapor. The dielectric vapor may rise through the dielectric liquid into a headspace of the immersion tank. In a single-phase immersion cooling, dielectric vapor may also be produced, but at a much lower rate than in two-phase immersion cooling.

Conventionally, immersion cooling may take place in an immersion cooling tank or bath that may be sealed or semi-open. In some applications, it is preferred that the bath be hermetically sealed to prevent the escape and loss of the dielectric vapor to the environment. Furthermore, dielectric fluid may be expensive to replace, so reducing vapor loss is desirable.

Problematically, maintenance of the IT equipment may be required from time to time, which is further complicated with a sealed bath that does not allow easy access to the IT equipment inside. For this reason, in some applications, a semi-open or selectively sealable bath may be preferred. Advantageously, a semi-open or a selectively sealable bath enables users to hot swap electronic or electric equipment or devices from the immersion cooling tank. In some applications, hot swap may refer to disconnecting and/or reconnecting an electronic device contained in the immersion tank while other electronic devices contained in the same immersion tank continue to operate. As previously mentioned, however, the semi-open or selectively sealable bath can still release large amounts of dielectric vapor to the atmosphere.

Alternative approaches to hot swapping provide unsatisfactory or unacceptable results. In one approach, all electronic devices in the immersion tank may be turned off or idled prior to swapping a device to eliminate heat production and resulting fluid vaporization. However, this approach may result in an undesirable loss of productivity and unacceptable down time. In another approach, a condenser in the immersion tank may be operated well below a standard operating temperature to promote more condensing of fluid vapor in the tank. This technique may be undesirably energy inefficient.

### BRIEF SUMMARY

In one aspect, a retractable cover sheet assembly for an immersion cooling system may include a case. The case may have side walls defining an opening. The assembly may include a first retractable cover sheet located above the opening of the case. The first retractable cover sheet may be movable from a first position to a second position to provide a sized opening smaller than the opening of the case. The assembly may include a condenser mounted to an interior surface of the case. The condenser may be configured to condense dielectric vapor at or near the sized opening. The condenser may be recessed from the sized opening to avoid interfering with objects being raised or lowered through the sized opening. The first retractable cover sheet may be configured to mount within an interior volume of an immersion tank. The first retractable cover sheet may be made of a flexible material that is configured to spool around a rotatable cylinder when in a retracted position. The retractable cover sheet assembly may be mounted to an interior surface of an immersion tank. The first retractable cover sheet may be stored along an interior wall of an immersion tank when in a retracted position. The assembly may include a second retractable cover sheet that is coplanar with the first retractable cover sheet. The assembly may include a motorized assembly that moves the first retractable cover sheet to adjust a dimension of the sized opening. The motorized assembly may include a linear guide system attached to the case and an electric motor coupled to the linear guide system. The linear guide system may be driven by the electric motor to displace both the first retractable cover sheet and the condenser. The first retractable cover sheet may be substantially impermeable to dielectric vapor.

In another aspect, a retractable cover sheet assembly for an immersion cooling system may include an adjustable case having an opening. The assembly may include a condenser attached to an interior surface of the adjustable case. The assembly may include a retractable cover sheet having a first edge and a second edge. The first edge may be attached to a rotatable cylinder, and the second edge may be attached to a top edge of the adjustable case. The assembly may include a motorized assembly configured to displace both the condenser and the second edge of the retractable cover sheet to adjust a dimension of the opening. The assembly may include a telescoping fluid delivery conduit fluidly connected to an inlet of the condenser. The assembly may include a telescoping fluid return conduit fluidly connected to an outlet of the condenser. The telescoping fluid delivery conduit and the telescoping fluid return conduit may allow the condenser to be displaced by the motorized assembly without fluid leakage. The adjustable case may include a first C-shaped portion and a second C-shaped portion that together define the opening and allow an area of the opening to be adjusted. The motorized assembly may include a guide block attached to an exterior surface of the adjustable case, a slide rail along which the guide block is configured to slide, and an electric motor configured to drive the motorized assembly. The assembly may include a containment structure attached to the adjustable case. The containment structure may surround and extend upward from the opening. The containment structure may be configured to increase a freeboard ratio of an immersion cooling system.

In yet another aspect, a retractable cover sheet assembly for an immersion cooling system may include a spring-loaded cylinder assembly. The spring-loaded cylinder assembly may include a first mounting bracket, a second mounting bracket, a fixed shaft having a first end fixedly attached to the first mounting bracket, and a rotary shaft having a first end rotatably attached to the second mounting bracket. A second end of the rotary shaft may be rotatably coupled to a second end of the fixed shaft. The spring-loaded cylinder assembly may further include a torsion spring positioned around the fixed shaft. A first end of the torsion spring may be attached to the first mounting bracket or the fixed shaft, and a second end of the torsion spring may be attached to the rotary shaft. The spring-loaded cylinder assembly may further include a cylinder positioned around the rotary shaft, the fixed shaft, and the torsion spring. The cylinder serving as a spring-loaded cylinder. The retractable cover sheet assembly may further include a cover sheet having a first edge attached to the cylinder. The cover sheet may be spooled around the cylinder when the torsion spring is in a relaxed state. Unspooling the cover sheet from the cylinder may store energy in the torsion spring. The retractable cover sheet may include a case having side walls defining an opening and a condenser mounted to an interior surface of the case. The condenser may be configured to condense dielectric vapor at or near the opening. A second edge of the cover sheet may be attached to the case. Moving the case in a first direction may cause the cover sheet to unspool from the cylinder. Moving the case in a second direction opposite the first direction may cause the cover sheet to spool around the cylinder. The retractable cover sheet assembly may include a press plate. The first edge of the cover sheet may be attached to the cylinder by the press plate. The retractable cover sheet assembly may include a bushing between the fixed shaft and the rotary shaft and a bearing between the rotary shaft and the second mounting bracket. A position of the edge of the cover sheet may be determined by a computer-controlled motorized assembly.

### BRIEF DESCRIPTION OF THE DRAWINGS

In the drawings, like reference characters generally refer to the same parts throughout the different views. Also, the drawings are not necessarily to scale, emphasis instead being placed upon illustrating principles of the invention. In the following description, various embodiments of the present invention are described with reference to the following drawings, in which:

FIG. 1 shows a cross-sectional front view of an immersion cooling system having a pair of retractable cover sheet assemblies mounted within an immersion tank that contains dielectric fluid and an electronic device immersed in the dielectric fluid.

FIGS. 2 and 3 show top perspective views of a retractable cover sheet assembly.

FIG. 4 shows a perspective view of a retractable cover sheet assembly.

FIG. 5 shows a perspective view of a retractable cover sheet assembly with an electric motor for tensioning the cover sheet.

FIG. 6 shows a perspective view of a retractable cover sheet assembly in a partially retracted position and configured as part of an immersion cooling system.

FIG. 6A shows an enlarged cross-sectional side view of a cylinder spooling assembly of the retractable cover sheet assembly of FIG. 6.

FIG. 7 shows a perspective view of a retractable cover sheet assembly fully covering an opening of an immersion tank.

FIG. 8 depicts a perspective view of a first cover sheet assembly and a second cover sheet assembly, each partially closed to form a first sized opening over an object in the tank.

FIG. 8A shows an enlarged cross-sectional side view of the cylinder of FIG. 8 spooling the retractable cover sheet assembly as it is wound around the cylinder assembly.

FIG. 9 shows a first cover sheet displaced over the immersion tank opening and a second cover sheet fully retracted to form a sized opening over an object in the tank.

FIG. 10 depicts a perspective view of a retractable cover sheet assembly that stores a cover sheet along an inner side of an immersion tank wall.

FIG. 10A shows a cross-sectional side view of the cover sheet of FIG. 10 being guided by the cylinder assembly during retracting of the cover sheet.

FIG. 11 shows a perspective view of the retractable cover sheet of FIG. 10 where the cover sheet is in a fully closed position.

FIG. 12 shows a perspective view of hot swapping a device from an immersion cooling system with retractable cover sheet assemblies.

FIG. 12A shows an enlarged portion of FIG. 12 with additional details.

FIG. 12B shows and enlarged portion of FIG. 12 with additional details.

FIG. 13 shows a perspective view of hot swapping a device while operating an immersion cooling system having retractable cover sheets that form a vapor seal as part of a containment structure

FIG. 13A shows an enlarged portion of FIG. 13 with additional details.

FIG. 13B shows an enlarged portion of FIG. 13A with additional details.

FIG. 14 shows a cross-sectional side view of hot swapping a device while operating an immersion cooling system having cover sheets that form a vapor seal as part of a containment structure.

FIG. 15 shows a cross-sectional side view of hot swapping a device while operating an immersion cooling system having gradient cover sheets that form a vapor seal within an opening of the immersion tank.

FIG. 16 shows a flow chart of an exemplary method of hot swapping an object from an immersion cooling system that includes an immersion tank and a retractable cover sheet assembly.

FIG. 17 shows a perspective view of a retractable cover sheet assembly with a spring-loaded cylinder assembly for tensioning the cover sheet.

FIG. 18 shows the retractable cover sheet assembly of FIG. 17 having an edge of the cover sheet attached to a case of the assembly and the cover sheet tensioned by the spring-loaded cylinder assembly.

FIG. 19 shows the retractable cover assembly of FIG. 17 with a lip removed.

FIG. 20 shows an enlarged view of FIG. 19 where the cover sheet is secured to the cylinder by a press plate.

FIG. 21 shows the retractable cover sheet of FIG. 19 where the cover sheet is spooled around the cylinder and fully retracted.

FIG. 22 shows the retractable cover sheet assembly of FIG. 19 with the cover sheet removed.

FIG. 23 shows the retractable cover sheet assembly of FIG. 22 with the cylinder removed and apart from remainder of the assembly.

FIG. 24 shows the retractable cover sheet assembly of FIG. 22 without the cylinder.

FIG. 25 shows an enlarged transparent view of the retractable cover sheet assembly of FIG. 24 where a rotary shaft is rotatably attached to a first mounting bracket.

FIG. 26 shows an enlarged transparent view of the retractable cover sheet assembly of FIG. 24 where a fixed shaft is fixedly attached to a second mounting bracket.

FIG. 27 shows an enlarged, partially transparent view of the retractable cover sheet assembly of FIG. 24 where the fixed shaft couples to the rotary shaft.

FIG. 28 shows an enlarged, partially transparent view of the retractable cover sheet assembly of FIG. 24 where the torsion spring attaches to the rotary shaft.

### DETAILED DESCRIPTION

An apparatus and method for reducing vapor loss from an immersion cooling system while hot swapping or servicing IT equipment therein are needed. Retractable covers are described herein that serve as practical solutions to this problem.

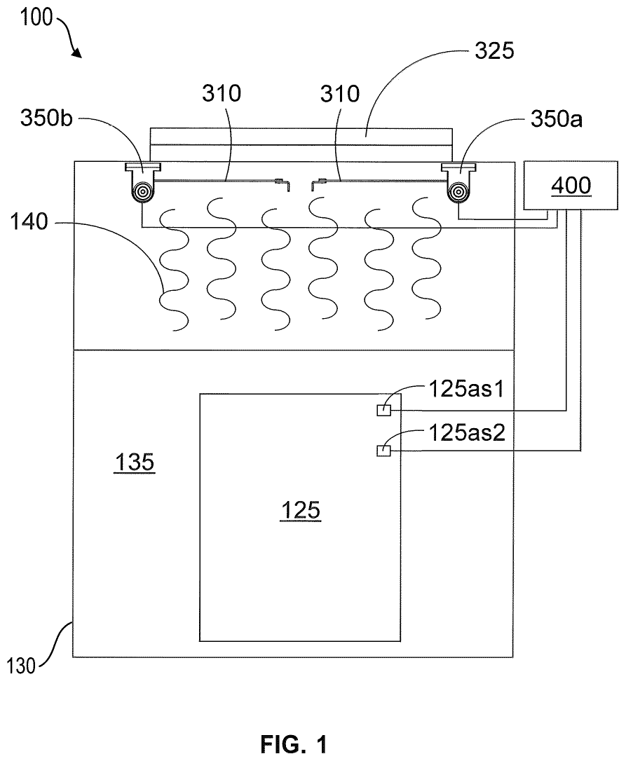

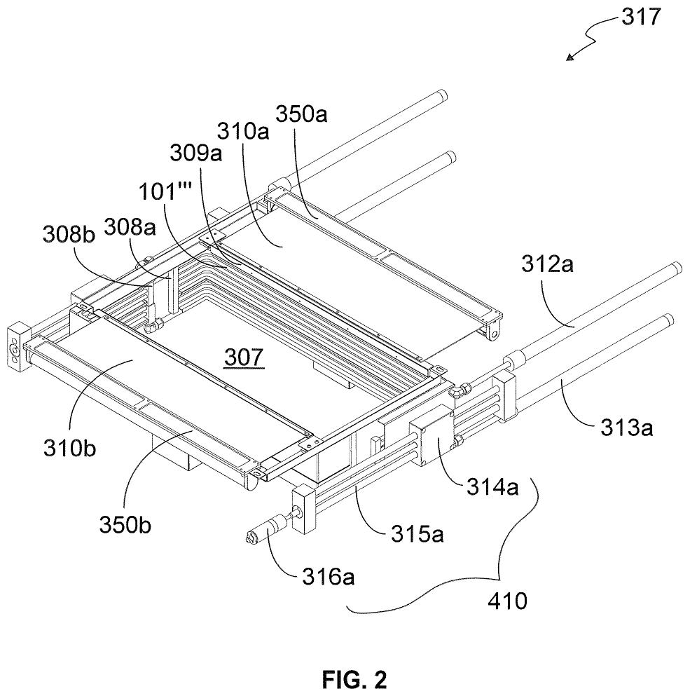

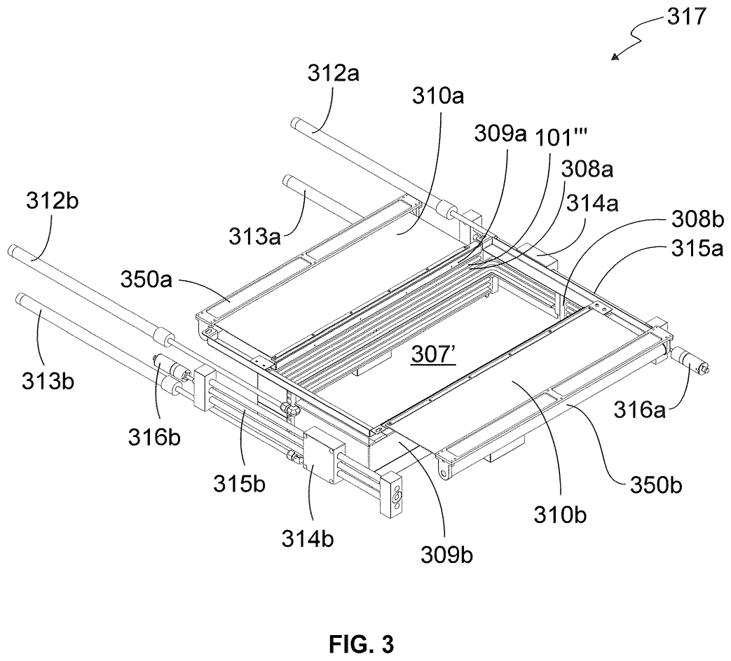

FIG. 1 shows an immersion cooling system (100). The immersion cooling system may include an immersion tank (130) and a retractable cover sheet assembly (317). The immersion tank may include a tank opening that is selectively covered by the retractable cover sheet assembly (317). In the example shown in FIGS. 2 and 3, the retractable cover sheet assembly (317) may include two retractable cover sheets (310) that can be moved to selectively cover an opening (110) of the immersion cooling tank (130). The cover sheet (310) may be substantially impermeable to dielectric vapor. The cover sheet (310) may be constructed from a flexible material that can be rolled for compact storage. The retractable cover sheet assembly (317) may be adjusted and/or tensioned by any suitable means of adjustment, including manually, electrically, pneumatically, or hydraulically, to cover an unused portion of the opening in the immersion cooling tank (130), to reduce fluid vapor loss. The retractable cover sheet assembly (317) may be adjusted from fully opened to fully closed, and any position in between.

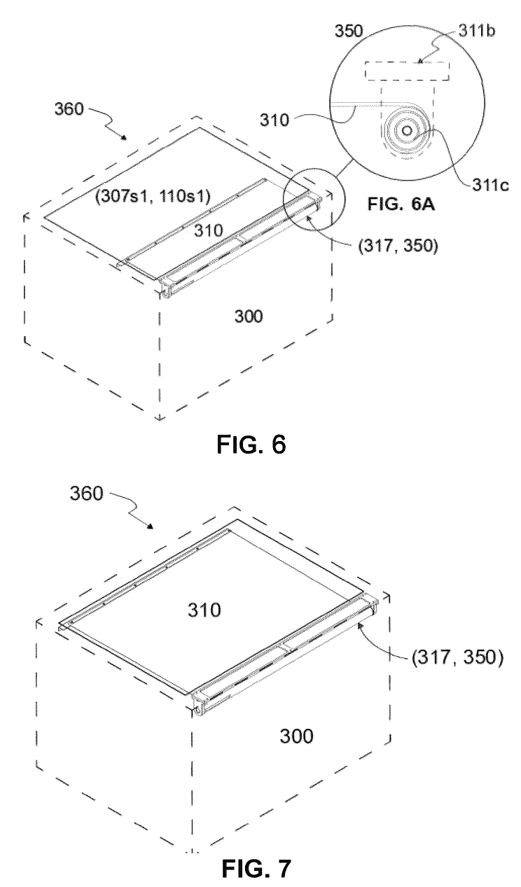

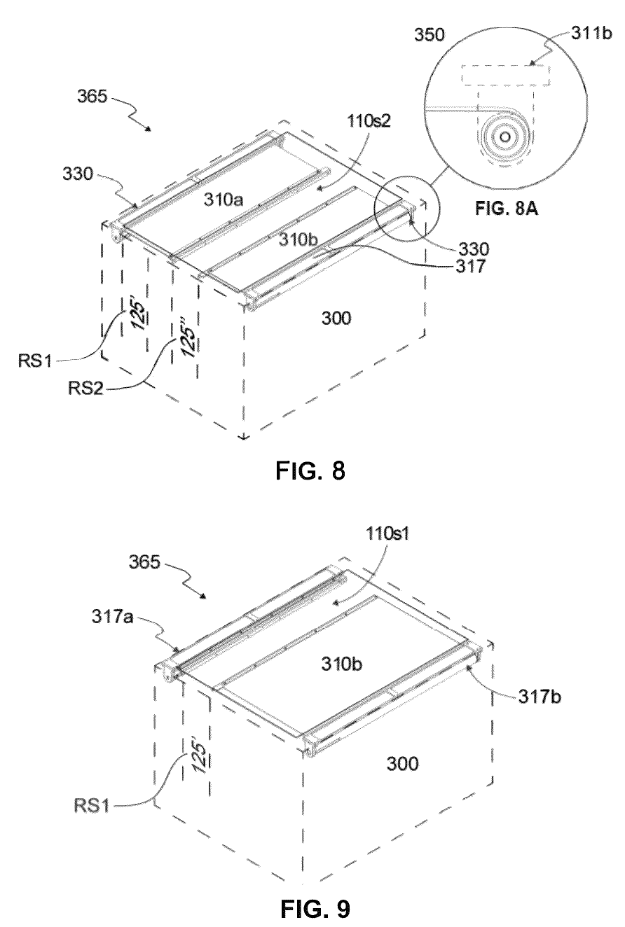

FIGS. 2 and 3 show top perspective views of the retractable covering sheet assembly (317) configured to fully or partially cover the opening (307, 307′, 110) of the immersion cooling tank. Retractable cover sheets (310a, 310b) may be operated by motor controllers (314a, 314b) to cover the tank opening (110s1-110s3), as shown in FIGS. 6 and 8-10. As shown in FIGS. 6 and 8, the cover sheets (310a, 301b) may be retracted and spooled around a cylinder assembly (350).

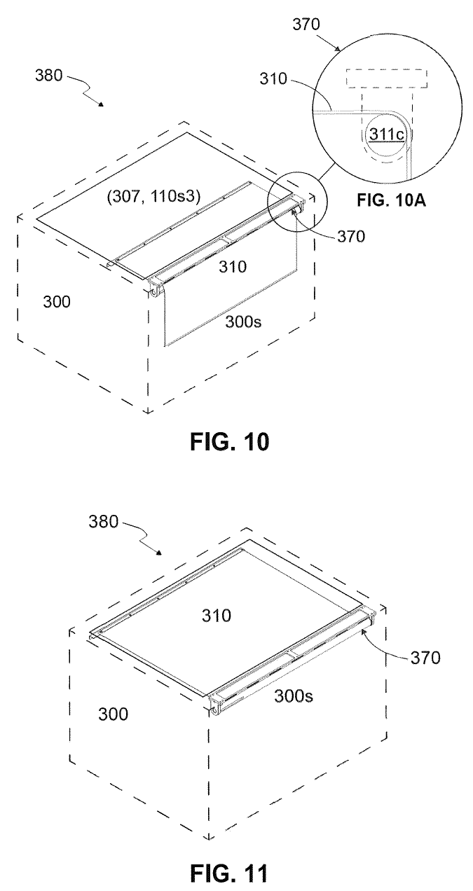

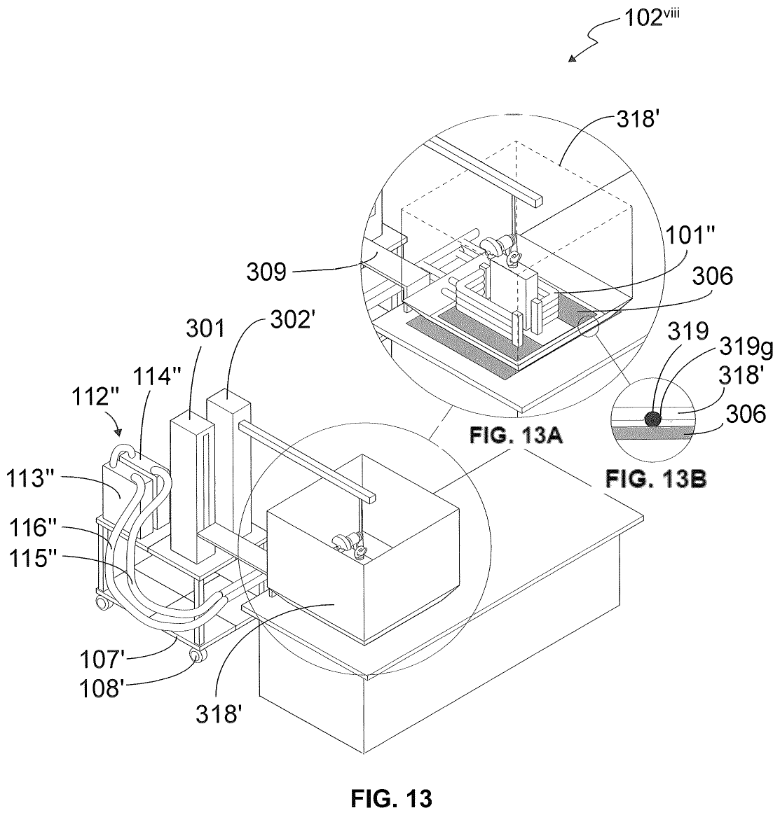

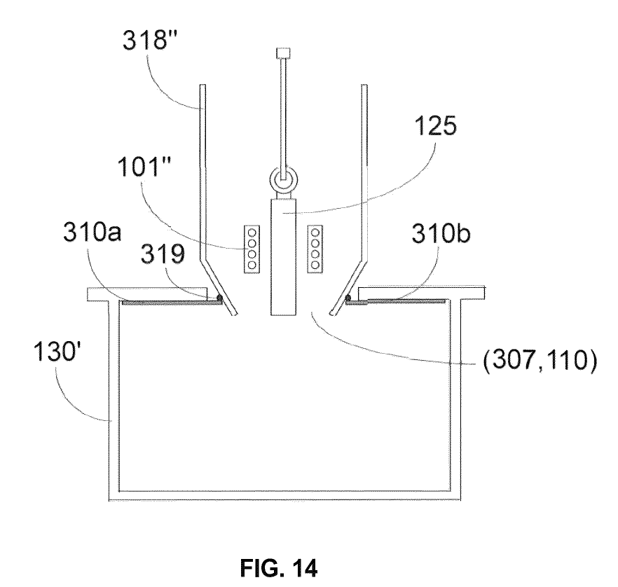

Alternately, the cover sheets (310a, 301b) may be displaced and stowed along an interior tank side wall (300s), as shown in FIG. 10 and FIG. 14. The cover sheets (310a, 310b) may be displaced under computerized motor control (refer to FIGS. 1, 2, 3, and 5) and may be stored parallel (see FIG. 13) and/or perpendicular (see FIG. 10) to the tank opening.

Still referring to FIGS. 2 and 3, the retractable cover sheet assembly (317) may include an adjustable case. In one example, the adjustable case may include two C-shaped case portions (309a, 309b) that are movable relative to each another to alter a dimension (e.g., a width) of the sized opening 307. The retractable cover sheet assembly (317) may include one or more thermally conductive elements (308a, 308b) attached to or formed as part of an adjustable case (309a, 309b), respectively, where the thermally conductive elements function as a condenser (101″′). Besides supporting the thermally conductive elements, the adjustable case (309a, 309b) may be configured to collect condensed dielectric liquid from the thermally conductive elements (308a, 308b). The condensed dielectric liquid may trail along the thermally conductive elements and be collected within a cavity of the adjustable case (309a, 309b) and returned to the tank.

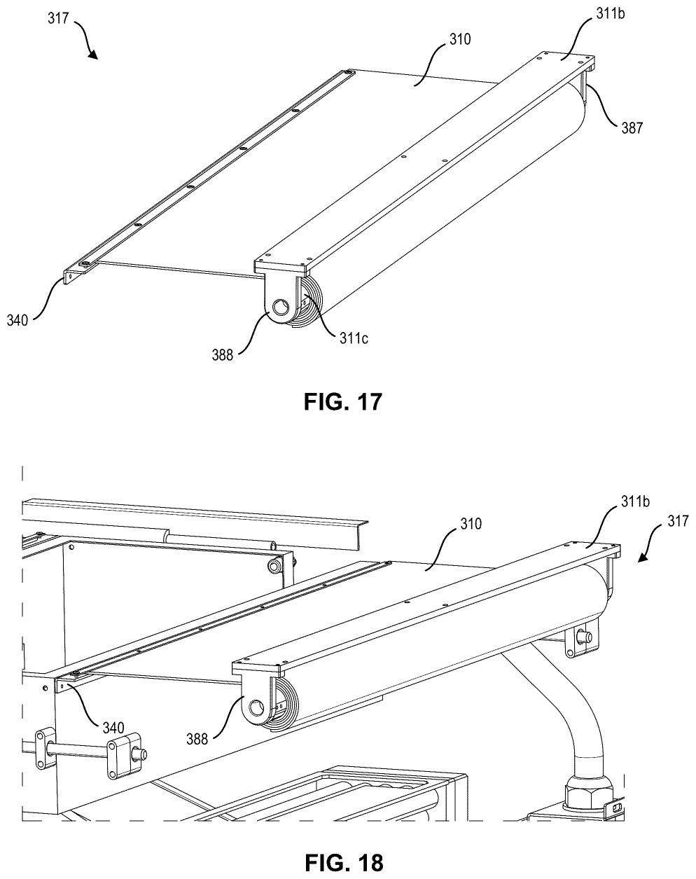

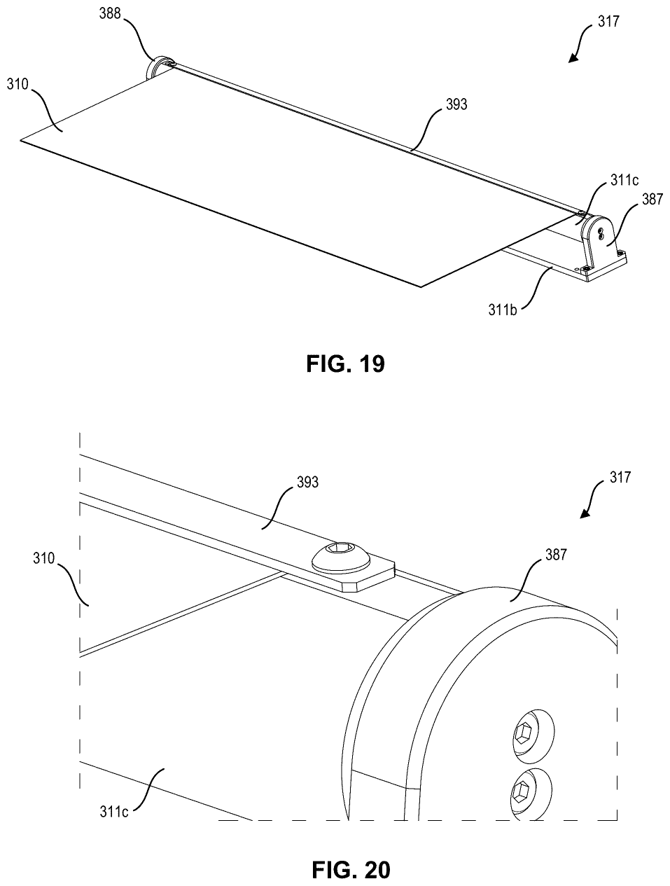

In examples where the case (309a, 309b) is adjustable, when altering the size of the case, it may be desirable to provide tension on the cover sheet (310), so the cover sheet does not sag and/or otherwise interfere with reliable operation of the retractable cover sheet assembly (317). Accordingly, the retractable cover sheet assembly (317) may include a means for tensioning the cover sheet (310). In the example of FIG. 5, the means for tensioning the cover sheet (310) may be an electric motor (336) attached to a shaft of the cylinder assembly (350). In the example of FIGS. 17-28, the means for tensioning the cover sheet (310) may be a spring-loaded cylinder assembly (397).

As shown in FIGS. 2 and 3, the retractable cover sheet assembly (317) may include a pair of linear guide system (315a, 315b) that are attached to the case and driven by the electric motors (316a and 316b), respectively. The linear guide systems (315a, 315b) and the thermally conductive elements (308a, 308b) may be under control of a computer system (400) (see FIG. 1) and be part of a motorized assembly (410). The linear guide systems (315a, 315b) may be driven by computer-controlled electric motors (316a, 316b). The motorized assembly (410) may include guide blocks (314a, 311b) that move along slide rails of the linear guide system (315a, 315b) to change the opening size of the case and the location of the thermally conductive elements (308a, 308b). The guide blocks (314a, 311b) may be attached to the adjustable case (309a, 309b).

Still referring to FIGS. 2 and 3, changing the position of the cover sheets (310a, 310b), by extending or retracting the cover sheets (310) relative to the tank opening (110), may also change the position of the thermally conductive elements (308a, 308b). As an example, the linear guide systems (315a, 315b) may include a ball screw and slide rails on opposing sides. The thermally conductive elements (308a, 309a) may be fluidly coupled to a coolant delivery conduit (312a, 312b) and a coolant return conduit (313a, 313b). As an example, the coolant delivery conduits (312a, 312b) and the coolant return conduits (313a, 313b) may be telescoping pipes that allow the conduits to be extended or retracted linearly during movement of the cover sheets of the retractable cover sheet assembly (317).

FIG. 1 shows a cross-sectional side view of the retractable cover sheet assembly (317) installed within the immersion cooling tank (130). During operation of the immersion cooling system (100), dielectric vapor (140) may be formed as dielectric liquid (135) receives heat from the IT equipment (125) (e.g., servers with microprocessors). The retractable cover sheet assembly (317) may be operated under computer control with electric motors, as shown in FIGS. 2 and 3, where each cover sheet (310a, 310b) may be retracted through a cylinder assembly (350a, 350b) and stored around a cylinder (311c) or slid along an interior side wall of the immersion tank prior to opening a tank lid (325). The cover sheet (310) may be spooled around the cylinder assembly (350), as shown in FIGS. 6A, 8A, 17, and 18. Deploying the retractable cover sheet assemblies (317) may vary the size of the sized openings (307) that are parallel to and offset from the tank opening (110). Properly adjusting the size and location of the sized opening (307, 307′, 110s1-110s3) may allow for the removal of objects (4U, 1U) from the immersion tank (130) while reducing dielectric fluid vapor (140) loss by reducing the size of the opening exposed to the atmosphere. Reducing the exposed area above the dielectric fluid (135) may reduce vapor (140) loss.

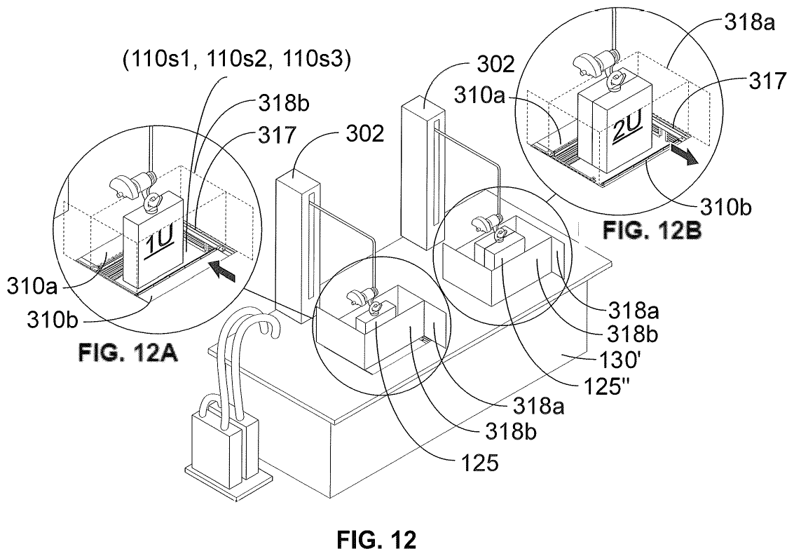

Still referring to FIG. 1, the object being cooled (125) may be one or more computer servers generating heat while operating. In one example, multiple servers may be arranged in a row within the immersion tank. The immersion cooling system (100) may include a means for determining a status and location of each server in the immersion tank 130. The location of each server may be communicated from each server to the immersion cooling system (100). For example, each server (125) may be configured to issue a signal (125as1, 125as2) through a wireless or wired communication network (e.g., via an Ethernet network) to the computer control system (400) of the immersion cooling system (100). The signal (e.g., 125as1, 125as2) may include information about the location of the server within the tank and/or information about server health and/or whether maintenance or servicing is required. Each server (125) may be programmed with a unique media access control (MAC) address. The signal or MAC address may be read by the motor controller interface (400) that operates the motorized retractable cover sheet assembly (317) to configure a sized opening (110s1, 110s2, 110s3) above the appropriate server or servers that require servicing. In one example, the server may be serviced in place (i.e., without requiring removal from the immersion tank). In another example, the server may be removed from the immersion tank (130) and dielectric fluid (135) and serviced outside the immersion tank. An example of a device for removing the server (125) from the immersion tank (130) is shown in FIG. 12. In one example, the one or more retractable cover sheet assemblies (317) can be deployed as part of an immersion cooling tank farm, as shown in FIG. 12. An immersion tank farm may include one tank (130) with multiple openings (110, 307) and/or multiple interconnected tanks with one or more openings (110, 307).

In some examples, the means for determining a status and location of each server in the immersion tank 130 may not rely on the signal (e.g., 125as1, 125as2) from the servers (125) to the computer control system (400). Rather, the immersion cooling system (100) may rely on optical recognition to determine the location of each server (125) within the immersion tank (130). In one example, the computer control system (400) may include a camera or barcode reader configured to read an identification tag, such as a machine-readable code (e.g., barcode or quick response (QR) code), affixed to each server. In another example, the computer control system (400) may include a radio frequency identification (RFID) reader, and each server may include a RFID tag.

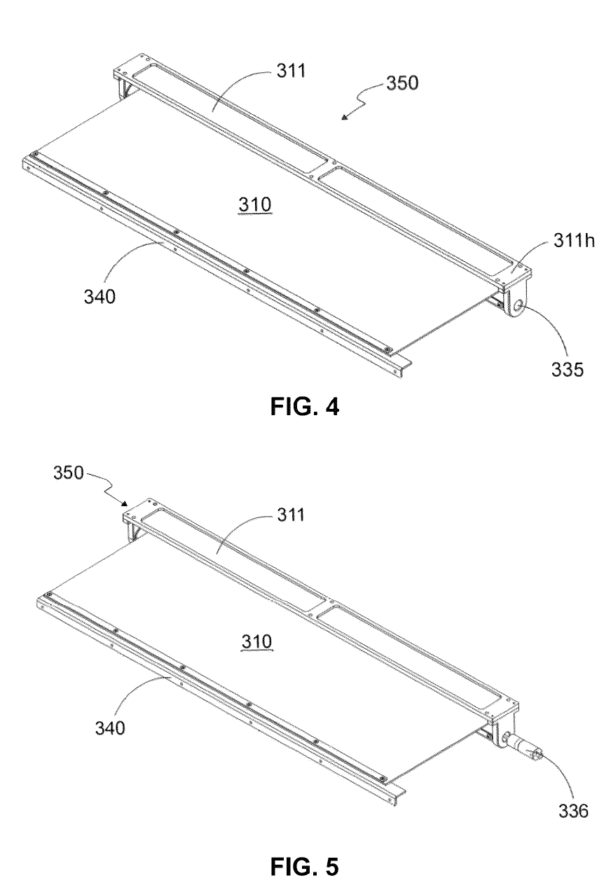

FIGS. 4 and 5 show an example cylinder assembly (350) of the retractable cover sheet assembly (317). The cylinder assembly (350) may include a cylinder (311c) sized to store the spooled cover sheet (310) when wrapped around the cylinder (311c). The cylinder (311c) may receive the spooled cover sheet (see FIG. 6A) or guide the cover sheet (310) that is stored along the inner wall of the tank side (300s) (see FIGS. 10 and 14). The cylinder assembly (350) may include a motor interface (335), as shown in FIG. 4, that is configured to accept an electric motor (336), as shown in FIG. 5. The electric motor (336) may be configured to rotate the cylinder (311c) and thereby spool the cover sheet (310) around the cylinder (311c). Alternately, the electric motor (336) may be configured to rotate the cylinder (311c) and thereby displace the cover sheet (310) along the interior surface of the tank side wall (300s) (see FIGS. 10 and 14). A computer control system (400) may be in communication with the electric motor (336). The computer control system (400) may control positioning of the cover sheets (310) to provide the sized opening having a proper size and location to permit access to the appropriate servers (125) in the immersion tank (130). As shown in FIGS. 4 and 5, the cylinder assembly (350) may include a lip (340) that is attached to a distal edge of the cover sheet (310). The lip (340) may attach to the case to secure the cover sheet (310) from distorting upward or downward relative to the opening (110) or moving laterally, when activated by the computer subsystem 400.

As shown in FIG. 1, the retractable cover sheet assembly (317) may be secured within the immersion tank (130) and located below the lid (325). Consequently, the retractable cover sheet assembly (317) may be located within the tank when the lid (325) is sealed, thereby avoiding the risk of the retractable cover sheet assembly (317) collecting dust, debris, or other airborne contaminants that could pollute the dielectric fluid and potentially harm the electronic devices immersed in the fluid 135.

Positioning the retractable cover sheet assembly (317) within the immersion tank (130) may reduce or avoid draft-out vapor loss when, for example, opening or closing the lid (325). In an immersion cooling system (100) without the retractable cover sheet assembly (317), draft-out vapor loss may occur when opening the lid (325), due to a pressure differential existing between the immersion tank headspace and the environment. Draft-out of vapor may also occur when closing the lid (325) due to the lid pushing air from the atmosphere into the headspace of the tank, which may in turn displace vapor from the tank. Positioning the retractable cover sheet assembly (317) within the immersion tank and proximate to the tank opening, as shown in FIG. 1, may reduce or avoid both scenarios of draft-out vapor loss.

During operation, the electric motor (336) may be activated to translate the cover sheet (310b) in a first direction to cover the tank opening (110). As shown in FIGS. 4 and 5, the condenser (101) may be located below the cover sheet (310b). For an immersion cooling system (100) with two cover sheets (310a, 310b), when the cover sheets are in the closed position, the first lip (340) of the first cover sheet (310a) may contact and/or seal against a corresponding lip (340) of the second cover sheet (310b). For an immersion cooling system (100) with one cover sheet (310), the lip of the cover sheet may contact and/or seal against a surface (310e) of the interior tank wall or case (309a, 309b) to seal the opening (110) of the immersion tank (130) before the lid (325) is opened to access the server (125). FIGS. 2 and 3 show the cover sheets (310a, 310b) partially retracted. The cover sheets (310) may be positioned by the computer control system 400 to provide the sized opening (e.g., 110, 110s1, 110s2, 110s3) that has a desired area and location to facilitate access to the servers (125) that require servicing.

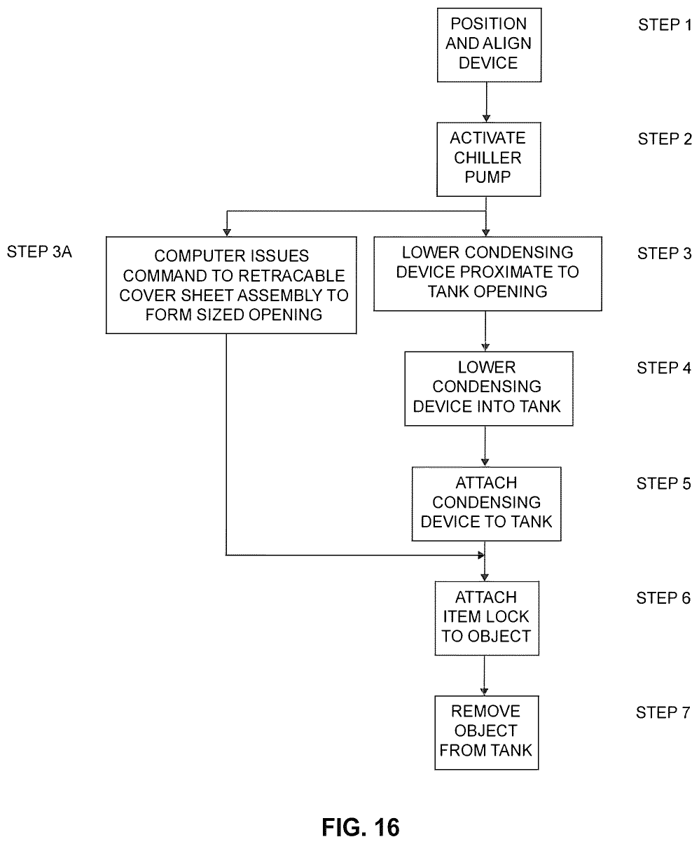

Comparing FIGS. 9 and 10, the areas of the sized openings (110s1, 110s3) are different. Comparing FIGS. 8 and 9, the locations of the sized openings (110s1) are different. When a server (125) needs to be serviced, the computer control system (400) may operate the electric motor(s) (336) to reposition the cover sheets (310a, 310b) to provide a sized opening (e.g., 110s1) in the desired location and with a suitable area to provide access to the server (125) that needs to be serviced. When the computer control system (400) determines that the area and location of the sized opening (e.g., 110s1) is proper to facilitate servicing of the server (125), the computer control system (400) may provide a signal indicating that it is safe to remove the lid (325) from the immersion tank (130). In one example, the signal may be provided to a human operator through a user interface, such as a computer monitor or colored indicator light. In one example, the lid (325) may be secured to the immersion tank (130) with mechanical latches that are under computer control to prevent the user from opening the latches and removing the lid (325) prematurely. In one example, the latches may not unlatch until an object retrieval device (102), such as a crane or hoist, is in position above the correct server (125). FIG. 16 shows steps of a method for retrieving an object, such as a server (125), from the immersion cooling system (100) while reducing vapor loss.

FIGS. 6 and 7 show the immersion cooling system (100) with one retractable cover sheet assembly (317) that includes a cover sheet (310) that can be extended (see FIG. 7) to fully cover the opening (110) in the immersion tank (30) and partially retracted (see FIG. 6) to provide a sized opening (110s1). FIG. 6A shows an enlarged cross-sectional side view of a portion of FIG. 6 to show the cover sheet (310) spooled around the cylinder (311c).

FIGS. 8 and 9 show the immersion cooling system (100) with two retractable cover sheet assemblies (317a, 317b). A dual retractable cover sheet assembly system (365) allows for varied sized opening (110s1, 110s2, 110s3) parallel to the opening 110 in the immersion tank (300). FIG. 9 shows the sized opening located above a first server (125′) located in a first rack slot (RS1) to provide access to the first server (125′) through the sized opening (110s1). Operating under computer control, the sized opening (110s2) may be repositioned from a first location above the first server 125′ (see FIG. 9) to a second location above a second server (125″) located in a second rack slot (RS2) to provide access to the second server (125″) through the sized opening (110s2).

One or more retractable cover sheet assemblies (317) may be deployed as part of the immersion cooling system (100) or tank farm to provide for varied sized openings (110s1, 110s2, 110s3). Referring to FIGS. 10 and 10A, the cover sheet (310) may be guided over the cylinder (311c) and then stored along an interior tank side wall (300s). In this example, the cover sheet (310) may not spool around the cylinder (311c). Rather, the cover sheet (310) may roll over a portion of the cylinder and be stored along the tank side wall (300s). Aside from this physical modification, the immersion cooling system in FIG. 10 may otherwise provide similar functionality as other embodiments described herein. Specifically, dielectric fluid vapor may be contained within the tank (300) when the cover sheet (310) is positioned to cover the tank opening, thereby reducing fluid vapor loss when the lid (325) is open or removed.

FIG. 12 shows an immersion cooling system (100) with several retractable cover sheet assemblies (317) and two lifting towers (302). Each lifting tower (302) may facilitate removal from and/or insertion into the immersion tank (130) of a server (125) during a servicing or hot swapping process. In one example, the immersion cooling system (100) may include an immersion tank with multiple openings. Each opening may be fitted with a containment structure (318) that is configured to vary in size corresponding to the varying size of the sized opening (110s1-110s3). In one example, each containment structure (318) may include two L-shaped plates (318a, 318b) that may be attached to the retractable cover sheets (310a, 310b), respectively. The L-shaped plates (318a, 318b) may be located very close to or touch each other along one or more edges that define the openings (307, 307′, 110s1-110s3). The containment structures (318) may reduce dielectric liquid loss by effectively increasing a freeboard ratio temporarily during a hot swap operation. The freeboard ratio may be defined as a length measured from a top of the condenser to a top of the immersion cooling tank, divided by a width or shorter dimension of the opening in the immersion tank. An increased freeboard ratio may reduce vapor loss when the lid (325) of the immersion tank is opened (e.g., during hot swapping or other servicing). By attaching the containment structure (318) to the retractable cover sheet assembly (317), the retractable cover sheet assembly may automatically reposition and resize the containment structure to achieve the freeboard ratio benefit when changing the area and location of the sized opening.

As shown in FIG. 12, when the electronic devices (125, 125′) are moved in and/or out of immersion cooling tank (130′), the retractable cover sheets (310a, 310b) are configured to be positioned near and above the outer perimeters of the electronic devices (1U, 2U), which then positions the L-shaped plates (318a, 318b) in corresponding locations. As a result, the area of the openings (307, 307′, 110s1-110s3) is surrounded by the L-shaped plates (318a, 318b), thereby limiting dielectric vapor loss. The containment structure (318) may be cooled by a condenser to further improve condensing of the dielectric vapor near the opening. The operation of the lifting towers (302) may be under computer control. In FIG. 12, “1U” represents an electronic device (125) having a size of one rack unit, and “2U” represents an electronic device (125) having a size of two rack units. Consequently, FIG. 12 shows that the retractable cover sheet assemblies (317) are compatible with a range of electronic device sizes.

As shown in FIG. 12B, when a larger electronic device (125′) needs to be moved into and/or out of immersion tank (130′), one or both retractable cover sheets (310a, 310b) may be moved to provide an appropriately sized opening (110s1-110s3) above the opening of the immersion tank (130′). This may provide access to the electronic device while reducing dielectric vapor loss. During repositioning of the cover sheets (310), one or both L-shaped plates (318a, 318b) may be positioned toward or away from the edge of the opening of immersion tank (130′) and near the sized opening formed by the retractable cover sheet assembly (317). As a result, the area of the opening, contained by L-shaped plates (318a, 318b), is adjustable. The L-shaped plates (318a, 318b) may be configured to cooperate with the retractable cover sheet assembly (317). The L-shaped plates (318a, 318b) may move relative to one another as the sized opening is formed by the retractable cover sheets (317). The L-shaped plates (318a, 318b) may be releasably attached to a wall of the adjustable case (309a, 309a), so as the cover sheets (310a, 310b) are displaced, the L-shaped plates are moved relative to one another to form an opening about the sized opening formed by the cover sheet(s).

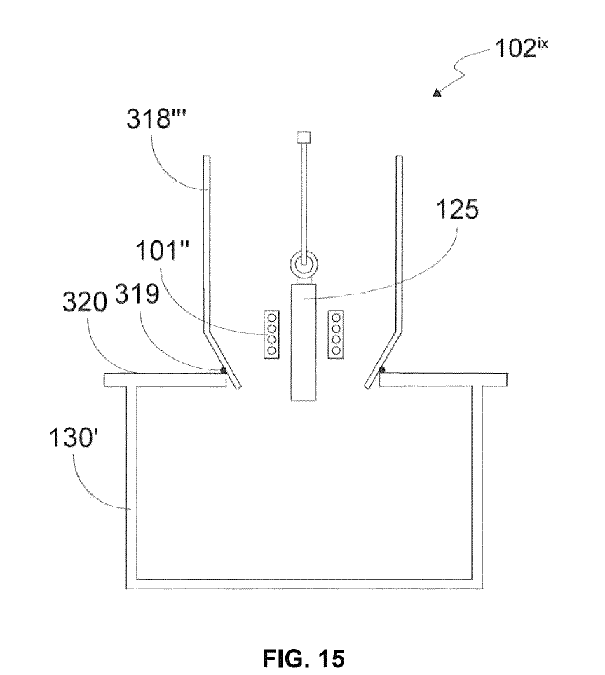

FIG. 13 shows a containment structure (318′) with a cover sheet (306). A movable hot swap apparatus (102^{viii}) may selectively adjust the height and location of the condensing device (101″) and containment structure (318′) relative to the tank opening. The containment structure (318′) may include a rectangular tube with a gradient at the bottom having a fixed opening on the top and bottom, with the opening at the top being greater than the opening at the bottom. As a non-limiting example, the vapor containment structure (318′) can be funnel shaped at the bottom, as shown in FIGS. 14 and 15. The containment structure (318′) may be removably or physically attached to a lifting tower (301) by an arm (309). The condensing device (101″) may be removably or permanently attached to the containment structure (318′) with a variable opening or a fixed opening. In one example, the lifting tower (302) may use a pulley system so that the movement of the vapor containment structure (318′) and movement of the electronic device (125) will not interfere with each other.

The containment structure (318′) may be moved over the cover sheet (306) to reduce fluid vapor loss. Optionally, the containment structure (318′) and cover sheet (306) may form a temporary gas tight seal at an interface edge where the containment structure (318′) and cover sheet (306) meet. As illustrated in FIG. 13B, the gas tight seal may be further improved by use of an O-ring (319) positioned in a groove (319g) of the containment structure (381′) to form a gas tight seal at the bottom of the containment structure (318′). The seal may reduce the loss of vapor or condensed liquid.

Dielectric vapor (140) that escapes through the sized opening of the cover sheet (310) may accumulate inside the containment structure (318), since the dielectric vapor may be heavier than air. Examples of dielectric fluids include NOVEC-7100, FC-72, and FC-3284 from 3M Company, headquartered in Mapleton, Minnesota. The dielectric vapor (140) that contacts or is near the condensing device (101″) may condense from a vapor to a liquid and then flow back into immersion tank (130′), assisted by gravity and the gradient at the bottom of containment structure (318′).

FIG. 14 shows a cross-sectional side view of the containment structure (318′) having a funnel or cone shape (318″) at one end instead of a rectangular shape disclosed in FIGS. 12 and 13. However, the principal to increase freeboard ratio is retained. The non-rectangular containment structure (318″) may allow the condensed dielectric fluid to flow inward toward the center of the tank opening formed by the sized opening to help limit fluid leakage along the containment structure edges that touch the immersion tank side. The containment structure (318″) may include a rectangular tube with one or more gradients at the bottom that extend through the opening of covering sheets (310a, 310b) positioned inside the opening of immersion tank (130′). The gradients, as described above, may assist with directing condensed dielectric fluid back to the immersion cooling tank (130′). While FIG. 14 illustrates cover sheets (310a, 310b) positioned inside the opening of the immersion tank (130′), the system may also work (i.e., help contain vapor) if the cover sheets are located on top of the opening of the immersion cooling tank (130′).

FIG. 15 shows a containment structure (318′″) positioned on a top surface (320) of the immersion tank (130′). This configuration may be desirable if the electronic device (125) undergoing hot-swap is significantly smaller in size than the opening (307, 307′, 110s1-110s3) of the immersion tank (130′). In this example, there may be no need to disrupt the cover sheet (306, 310a, 310b) to obtain a much smaller secondary opening within the cover sheet to access the electronic device (125).

Having described an apparatus for hot swapping electronic devices from an immersion cooling system, a method of hot swapping electronic devices from an immersion cooling system will now be described. Advantageously, the methods described herein may occur while other electronic devices in the immersion cooling system continue to operate, generate heat, and cause fluid in the tank to vaporize.

FIG. 16 shows an exemplary flow chart of a method for deploying the retractable cover sheet assembly (317) of an immersion cooling system. Each step may be under computer control or performed manually. With the lid (325) secured, STEP 1 may include positioning and/or aligning the device, e.g., using the movable platform and/or lifting arm of the hot swap assemblies described herein. Contemporaneously with positioning and aligning the condensing device (STEP 1), a chiller pump (112) may be activated to initiate the flow of coolant through the condensing device (101, 309a, 309b), (STEP 2). STEP 3 may include lowering the condensing device (101) toward the immersion tank opening. Prior to retrieving the object (125) from the immersion tank, a coolant flow rate and thus coolant temperature may be adjusted to selectively and actively control condensation of the heat transfer fluid vapor once the condensing device (101) has been lowered proximate to the opening (110) of the immersion tank (STEP 3). Those of ordinary skill in the art will appreciate that a chiller pump may be activated to initiate the flow of coolant through the condensing device (STEP 2) at any time before the item lock, and object(s) to be removed from the tank, are raised out of the heat transfer fluid bath (STEP 5).

Still referring to FIG. 16, once the coolant flow rate and temperature of the condensing device reach a target setpoint, the condensing device (101) may be lowered into the opening of the immersion tank (STEP 4). In some implementations, the condensing device may be lowered into the opening until the outer rim portion of the condensing device forms a full or a partial seal with the rim at the opening of the immersion tank. In other implementations, after the condensing device has been lowered into the opening of the immersion cooling tank (STEP 4), the condensing device may be releasably attached to a flange disposed about the rim of the immersion cooling tank, e.g., using a snap catch, a locking detainer, a plurality of sliding position locks, and the like (STEP 5). Advantageously, once the outer rim portion of the condensing device forms a full or partial seal with the immersion tank, the size of the opening of the immersion tank has been reduced to the size of the opening in the condensing coil. As a result, the area available for heat transfer fluid vapor to escape is reduced.

Still referring to FIG. 16, while the immersion tank is still covered, the device may be positioned, e.g., using the movable platform and/or lifting arm, such that the condensing device is aligned with the opening of the immersion tank (STEP 1). After the condensing device has been lowered proximate to the opening of the immersion cooling tank (STEP 2) lowering the condensing device into the opening of the immersion cooling tank (STEP 3) may be optional since it is not required for condensing device to be placed at or above the opening of the immersion cooling tank. Moreover, attaching the condensing device to a flange disposed about the rim of the immersion tank, e.g., using a snap catch, a locking detainer, a plurality of sliding position locks, and the like, may also be optional (STEP 4).

Subsequently, an item lock may be lowered into the heat transfer fluid bath, through the opening in the condensing device, and the item lock may be releasably attached to the object(s) to be removed from the heat transfer fluid bath (STEP 6). Lowering the item lock may be performed manually, e.g., using a hand crank and a winch, or automatically, e.g., using a hoisting/pulley system, chain hoist/forklift system, and so forth. FIGS. 12-15 show the item lock. Connecting to and/or capturing the object (125) may be performed manually by an operator or by means of a self-aligning/self-adjusting capability of the item lock to detect and attach to/clutch the object under computer control.

Once the object to be removed has been captured/secured by the item lock, the item lock and object may then be raised out of the heat transfer fluid bath (STEP 7), through the opening in the condensing device. For example, the item lock and object may be raised manually, e.g., using a hand crank and winch, or automatically, e.g., using a hoisting/pulley system, a chain hoist/forklift system, and so forth. After the heat transfer fluid on exterior surfaces of the object has been allowed to drain back into the immersion tank, the object may then be released from the item lock and retrieved or removed.

To reinstall the removed object (125) and/or to insert a replacement object in its place, either procedure described hereinabove may be reversed. Using the exemplary method, for example, the replacement object may be attached to the item lock. The item lock and replacement object may then be lowered into the heat transfer fluid bath, through the opening in the condensing device. For example, lowering may be performed manually, e.g., using a hand crank and a winch, or automatically, e.g., using the hoisting/pulley system, the chain hoist/forklift system, and so forth. After the replacement object is correctly positioned, the item lock may release the replacement object and the item lock may be removed from the heat transfer fluid bath, through the opening in the condensing device. For example, the item lock and object may be raised manually, e.g., using a hand crank and a winch, or automatically, e.g., using the hoisting/pulley system, the chain hoist/forklift system, and so forth.

Once the item lock has been raised sufficiently to clear the opening in the condensing device, the condensing device may be raised, e.g., using lifting device, from the opening of the immersion cooling tank. Alternatively, the item lock and the condensing device may be raised simultaneously. The cover (325) may then be reinstalled to hermetically seal the immersion tank.

After STEPS 1 and 2 are completed, deploying the retractable cover sheet assembly (317) under computer control may eliminate STEPS 3, 4, and 5. This may result in reduced turn-around time, which may reduce dielectric vapor loss and result in increased up-time at a data center. At STEP 3A, a computer (400) may issue a command to establish dimensions and location of the sized opening (110s1-110s3), as described herein. After the condenser (309a, 309b) is operating and achieving target system parameters, the lid (325) may be unlocked and removed. Then, STEPS 6 and 7 may be completed. Then, the tank opening may be covered with the cover sheet(s), and the lid (325) may be reinstalled. The lid (325) may be closed under computer control or manually.

To prevent draft-out vapor loss in the method of FIG. 16, prior to opening the lid (325), the retractable cover sheet assembly (317) may be fully closed. Similarly, to prevent draft-out vapor loss in the method of FIG. 16, prior to closing the lid (325), the retractable cover sheet assembly (317) may be fully closed. In both instances, the presence of the retractable cover sheet assembly (317) near the tank opening may serve to inhibit gas exchange between the headspace of the immersion tank and the atmosphere, thereby reducing dielectric vapor loss.

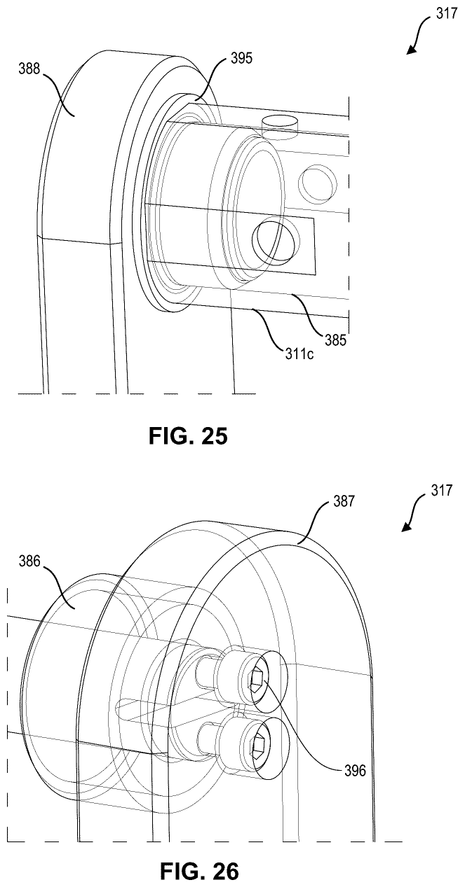

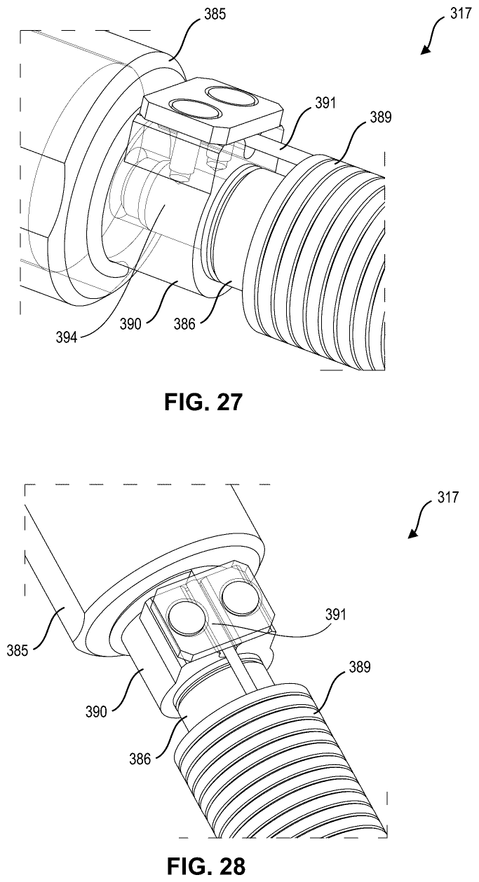

FIG. 17 shows a perspective view of the retractable cover sheet assembly (317). The retractable cover sheet assembly (317) may include a base (311b) that allows the assembly to be mounted, for example, to an inner surface of the immersion tank. A first mounting bracket (387) may be located at or proximate to a first end of the base (311b). A second mounting bracket (388) may be located at or proximate to a second end of the base (311b). The retractable cover sheet assembly (317) may include a rotary shaft (385) coupled to a fixed shaft (386), as shown in FIGS. 24, 27, and 28. The rotary shaft (385) may be rotatably attached to the first mounting bracket (387), as shown in FIG. 25. A bearing (395) may be included between the rotary shaft (385) and the first mounting bracket (387) to provide rotatable attachment. The fixed shaft (386) may be fixedly attached to the second mounting bracket (388), as shown in FIG. 26. One or more fasteners (396) may be included to fixedly attach the fixed shaft to the second mounting bracket. A bushing (390) may be included at the coupling between the rotary shaft (385) and the fixed shaft (386). The bushing (390) may allow the rotary shaft (385) to rotate while the fixed shaft remains stationary. In the nonlimiting example shown in FIGS. 27 and 28, the bushing (390) may be integral to the rotary shaft (385), and the fixed shaft (386) may include a male end (394) that inserts into the bushing (390). Lubrication may be provided between the bushing (390) and the male end (394) of the fixed shaft (386) to facilitate rotation. Alternatively, the bushing (390) may be a self-lubricating bushing.

The retractable covers sheet assembly (317) may include a torsion spring (389). The torsion spring (389) may be positioned around the fixed shaft (386), as shown in FIGS. 27 and 28. The fixed shaft (386) may be positioned in an interior volume of the torsion spring (389). The torsion spring may have a fixed end and a rotatable end, thereby allowing it to store mechanical energy. For example, a first spring end (391) of the torsion spring (389) may be secured to the rotary shaft (385), as shown in FIGS. 27 and 28. A second spring end of the torsion spring (389) may be attached to the first mounting bracket (387) or the fixed shaft (386). Consequently, rotating the rotary shaft (385) in a first direction may serve to store mechanical energy in the torsion spring (389). Conversely, rotating the rotary shaft (385) in a second direction opposite the first direction may serve to deplete stored energy from the torsion spring. Although a torsion spring (389) is shown and described, other suitable devices for storing mechanical energy may be substituted for the torsion spring.

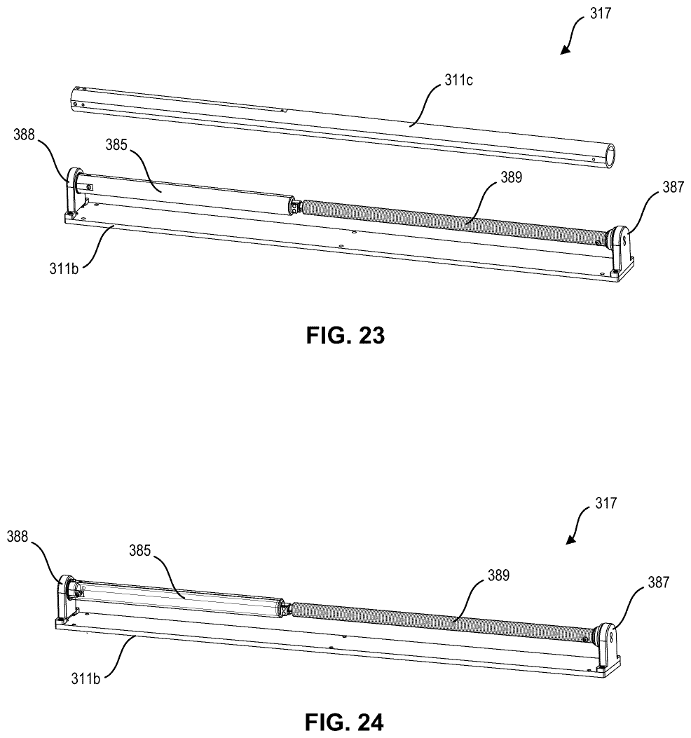

The retractable cover sheet assembly (317) may include a cylinder (311c), as shown in FIGS. 22 and 23. The cylinder (311c) may be installed around the fixed shaft (386) and the rotary shaft (385), as shown in FIG. 22. The cylinder (311c) may be attached to the rotary shaft (385) and configured to rotate in unison with the rotary shaft (385). The assembly shown in FIG. 22 may serve as a spring-loaded cylinder assembly 397. The spring-loaded cylinder assembly 397 may negate the need for the electric motor 336 shown in the example of FIG. 5, since the spring-loaded cylinder may be capable of tensioning the cover sheet 310 during use (e.g., during resizing of the case).

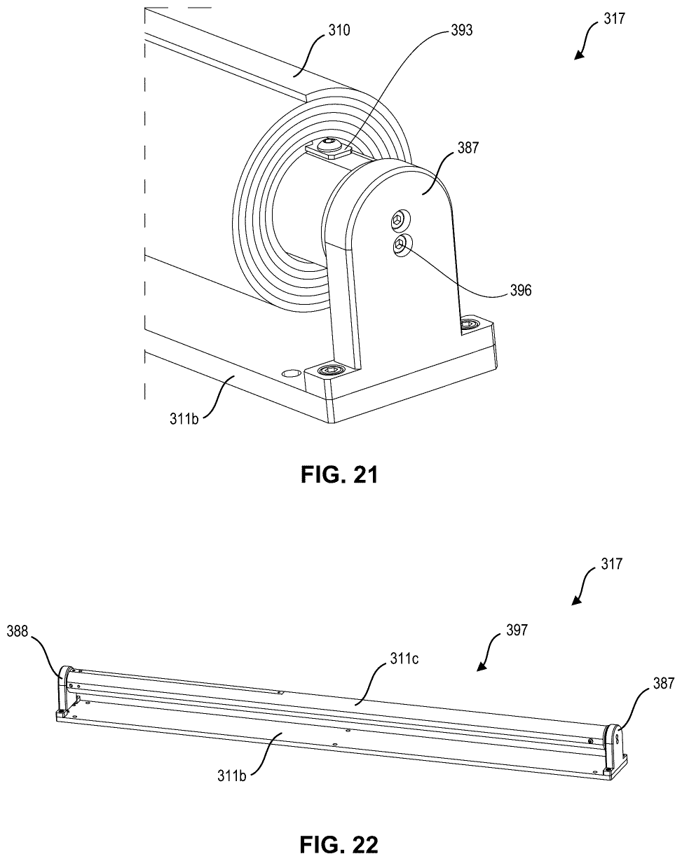

The cover sheet (310) may be attached to an exterior surface of the cylinder (311c) by a press plate (393), as shown in FIG. 20. The press plate (393) may be attached to the cylinder (311c) by any suitable fasteners, such as screws. An edge of the cover sheet (310) may be captured and secured between the press plate (393) and the cylinder (311c). The torsion spring (389) may be configured to store the cover sheet (310) in a fully spooled (i.e., retracted) position when in a relaxed state (i.e., an unloaded position). Rotating the cylinder (311c) in the first direction may serve to unspool the cover sheet (310) from the cylinder and store mechanical energy in the torsion spring (389). Conversely, allowing the cylinder (311) to rotate in a second direction opposite the first direction may serve to spool the cover sheet (310) around the cylinder (311c), as shown in FIG. 21, and release stored energy from the torsion spring (389).

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

What is claimed is:

1. A retractable cover sheet assembly for an immersion cooling system, the assembly comprising:
a case having side walls defining an opening; and
a first retractable cover sheet located above the opening of the case, the first retractable cover sheet being movable from a first position to a second position to provide a sized opening smaller than the opening of the case.

2. The retractable cover sheet assembly of claim 1, further comprising:
a condenser mounted to an interior surface of the case, the condenser configured to condense dielectric vapor at or near the sized opening,
wherein the condenser is recessed from the sized opening to avoid interfering with objects being raised or lowered through the sized opening.

3. The retractable cover sheet assembly of claim 1, wherein the first retractable cover sheet is configured to mount within an interior volume of an immersion tank.

4. The retractable cover sheet assembly of claim 1, wherein the first retractable cover sheet comprises a flexible material and is configured to spool around a rotatable cylinder when in a retracted position.

5. The retractable cover sheet assembly of claim 4, wherein the retractable cover sheet assembly is configured to mount to an interior surface of an immersion tank.

6. The retractable cover sheet assembly of claim 1, wherein the first retractable cover sheet is configured to be stored along an interior wall of an immersion tank when in a retracted position.

7. The retractable cover sheet assembly of claim 1, further comprising a second retractable cover sheet that is coplanar with the first retractable cover sheet.

8. The retractable cover sheet assembly of claim 1, further comprising a motorized assembly that moves the first retractable cover sheet to adjust a dimension of the sized opening.

9. The retractable cover sheet assembly of claim 2, further comprising a motorized assembly comprising:
a linear guide system attached to the case; and
an electric motor coupled to the linear guide system,
wherein the linear guide system is driven by the electric motor to displace both the first retractable cover sheet and the condenser.

10. The retractable cover sheet assembly of claim 1, wherein the first retractable cover sheet is substantially impermeable to dielectric vapor.

11. A retractable cover sheet assembly for an immersion cooling system, the assembly comprising:
an adjustable case having an opening;
a condenser attached to an interior surface of the adjustable case;
a retractable cover sheet having a first edge and a second edge, the first edge being attached to a rotatable cylinder and the second edge being attached to a top edge of the adjustable case; and
a motorized assembly configured to displace both the condenser and the second edge of the retractable cover sheet to adjust a dimension of the opening.

12. The retractable cover sheet assembly of claim 11, further comprising:
a telescoping fluid delivery conduit fluidly connected to an inlet of the condenser; and
a telescoping fluid return conduit fluidly connected to an outlet of the condenser,
wherein the telescoping fluid delivery conduit and the telescoping fluid return conduit allow the condenser to be displaced by the motorized assembly.

13. The retractable cover sheet assembly of claim 11, wherein the adjustable case comprises a first C-shaped portion and a second C-shaped portion that together define the opening and allow an area of the opening to be adjusted.

14. The retractable cover sheet assembly of claim 11, wherein the motorized assembly comprises:
a guide block attached to an exterior surface of the adjustable case;
a slide rail along which the guide block is configured to slide; and
an electric motor configured to drive the motorized assembly.

15. The retractable cover sheet assembly of claim 11, further comprising a containment structure attached to the adjustable case, the containment structure surrounding and extending upward from the opening, wherein the containment structure is configured to increase a freeboard ratio of an immersion cooling system.

16. A retractable cover sheet assembly for an immersion cooling system, the assembly comprising:
a spring-loaded cylinder assembly comprising:
a first mounting bracket;
a second mounting bracket;
a fixed shaft having a first end fixedly attached to the first mounting bracket;
a rotary shaft having a first end rotatably attached to the second mounting bracket, a second end of the rotary shaft being rotatably coupled to a second end of the fixed shaft;
a torsion spring positioned around the fixed shaft, a first end of the torsion spring being attached to the first mounting bracket or the fixed shaft, a second end of the torsion spring being attached to the rotary shaft; and
a cylinder positioned around the rotary shaft, the fixed shaft, and the torsion spring, the cylinder serving as a spring-loaded cylinder; and
a cover sheet having a first edge attached to the cylinder,
wherein the cover sheet is spooled around the cylinder when the torsion spring is in a relaxed state, and
wherein unspooling the cover sheet from the cylinder serves to store energy in the torsion spring.

17. The retractable cover sheet assembly of claim 16, further comprising:
a case having side walls defining an opening; and
a condenser mounted to an interior surface of the case, the condenser configured to condense dielectric vapor at or near the opening,
wherein a second edge of the cover sheet is attached to the case,
wherein moving the case in a first direction causes the cover sheet to unspool from the cylinder and moving the case in a second direction opposite the first direction causes the cover sheet to spool around the cylinder.

18. The retractable cover sheet assembly of claim 16, further comprising a press plate, wherein the first edge of the cover sheet is attached to the cylinder by the press plate.

19. The retractable cover sheet assembly of claim 16, further comprising a bushing located between the fixed shaft and the rotary shaft and a bearing located between the rotary shaft and the second mounting bracket.

20. The retractable cover sheet assembly of claim 16, wherein a position of the edge of the cover sheet is determined by a computer-controlled motorized assembly.
